(19) United States
(12) Patent Application Publication
(10) Pub. No.: US 2007/0290214 A1
(43) Pub. Date: Dec. 20, 2007

(54) LIGHT EMITTING DIODE STRUCTURE

(75) Inventors: CHIN-FU KU, TAINAN COUNTY (TW); MING-SEN HSU, TAINAN COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: EPILEDS TECH INC., TAINAN COUNTY (TW)

(21) Appl. No.: 11/762,344

(22) Filed: Jun. 13, 2007

(30) Foreign Application Priority Data
Jun. 14, 2006 (TW) 095210400

(51) Int. Cl. H01L 33/00; H01L 31/12; H01L 27/15; H01L 29/26

(52) U.S. Cl. 257/79

(57) ABSTRACT

A LED (Light Emitting Diode) structure with a contact layer of a multiple structure includes a nucleation layer disposed on a substrate; a conductive buffer layer disposed on the nucleation layer; an active layer disposed between an upper and a lower confinement layer, wherein the structure of active layer includes a semiconductor material mainly doped with III-V group; the contact layer made of the multilayer structure disposed on the upper confinement layer; and a transparent electrode disposed on the contact layer made of a multilayer structure; and an electrode contacted with the conductive buffer layer and isolated from the active layer and the transparent electrode.

### BACKGROUND OF INVENTION

1. Field of the Invention

The present invention generally relates to a light emitting diode (LED), and more particularly to a LED structure which has a contact layer made of a multilayer structure.

2. Description of Related Art

LED elements made of compound semiconductor materials have recently attracted the attention of many people. FIG. 1 depicts a sectional view of a LED doped with commonly used III-V group elements. As shown in FIG. 1, the LED is formed on a substrate 10 such as Al₂O₃ (aluminum oxide) substrate. A nucleation layer 12 and an N-type conductive buffer layer 14 are on the substrate 10 in order. The buffer layer 14 doped with N-type GaN (gallium nitride) is used for smoother subsequent crystal growing. An active layer 18 for light emitting is on the buffer layer 14, where an upper and lower confinement layer or cladding layers 16, 20 are formed. The lower confinement layer 16 is doped with N-type GaN when the upper confinement layer 20 is doped with P-type GaN. Then, a contact layer 22 is formed on the upper confinement layer 20 doped with P-type GaN. Next, a transparent electrode 24 is formed. The transparent electrode is generally doped with N-type materials such as Indium tin oxide, Cadmium tin oxide or thin metals, and acts as anode of the diode. In addition, an electrode 26 (cathode of diode) contacts with the buffer layer 14, and is isolated from the active layer 18 and the confinement layers 16, 20. Further, a metal pad 28 is disposed on the transparent electrode 24.

FIG. 2 depicts a schematic view of the light emitting range of the LED shown in FIG. 1. As shown in FIG. 1, when a forward bias is applied to electrodes 24, 26 of the diode, the diode is conducted, and the current flows from the electrode 24 to the active layer 18. The conventional P-type GaN contact layer yields poorer current spreading effect due to extremely high carrier concentration and contact resistance, and the P-type electrode 24 only covers a portion of the contact layer. The current only flows through a region equivalent to the width L of the electrode 24 in FIG. 2. Consequently, the light emitting area of the diode is restrained, and it is unable to take full advantage of the active layer, thereby reducing the luminous efficiency of the diode substantially.

As a whole, the high concentration P-type doped layer cannot grow efficiently since the conventional diode structure is limited due to the physical characteristics of the contact layer, so the manufacture cost of the diode will be increased, and the yield rate will be reduced. Moreover, the conventional diode structure cannot provide a diode of high luminous efficiency, namely, most of the active layer in the diode is not fully utilized, and a different doped material (electrically conducting material) of the contact layer is not identical to the transparent electrode. Consequently, a junction may occur between the transparent electrode and the contact layer to influence the operation of the diode.

### SUMMARY OF THE INVENTION

Thus, one purpose of the present invention is to provide an LED structure to form a contact layer of multilayer structure, thus making it easier to generate a contact layer of high concentration (high conductivity).

The present invention provides an LED structure, which could increase the luminous efficiency and reduce the operating voltage by using the contact layer of the multilayer structure and a proper transparent electrode.

As for the LED structure of the present invention, the contact layer of the multilayer structure and the transparent electrode have a better contact characteristic, and the size of the transparent electrode is almost identical to the active layer to enhance the current flowing through the area of the active layer so as to increase the light emitting area of the active layer, thereby enhancing the luminous efficiency.

To achieve the foregoing purpose, the LED structure of the present invention comprises a substrate, a first confinement layer, an active layer, a second confinement layer, a contact layer, a transparent electrode and a cathode. A nucleation layer and a conductive buffer layer are disposed on the substrate in order. The first confinement layer is disposed on the conductive buffer layer. The first confinement layer includes a doped material (electrically conducting material) which equals to a doped material of the conductive buffer layer. The active layer is disposed on the first confinement layer. The active layer is composed of the semiconductor material mainly doped with III-V group elements. The second confinement layer is disposed on the active layer, and the second confinement layer includes a doped material (electrically conducting material) which is not identical to the doped material of the first confinement layer. The contact layer is disposed on the second confinement layer, and is a multilayer structure. The transparent electrode is taken as an anode, and disposed on the contact layer. The cathode is contacted with the conductive buffer layer, and isolated from the first and second confinement layer, the active layer, the contact layer and the anode.

The aforementioned contact layer includes a P-type conducting material, while the transparent electrode and the contact layer include the P-type or N-type conducting material. Alternatively, the transparent electrode and the contact layer can have different conducting materials.

The present invention also provides an LED structure with a contact layer composed of a multilayer structure. The LED structure comprises a substrate, an active layer structure, a contact layer of multilayer structure, a transparent electrode and another electrode. A conductive buffer layer is disposed on the substrate. The active layer structure is disposed on the conductive buffer layer, and composed of a semiconductor material mainly doped with III-V group elements. The contact layer of multiple structure is disposed on the active layer structure. The transparent electrode is disposed on the contact layer. The electrode is contacted with the conductive buffer layer, and also isolated from the active layer structure and the transparent electrode.

The aforementioned contact layer includes a P-type conducting material, while the transparent electrode and the contact layer include the P-type or an N-type conducting material. Alternatively, the transparent electrode and the contact layer can have different conducting materials.

### BRIEF DESCRIPTION OF THE DRAWINGS

FIG. 1 shows a cross-sectional view of a conventional LED containing III-V group.

FIG. 2 shows a view of a light emitting range of a LED shown in FIG. 1.

FIG. 3 shows a cross-sectional view of a LED structure containing III-V group in accordance with the preferred embodiment of the present invention.

FIG. 4 shows a view of the light emitting range of a LED shown in FIG. 3.

### DETAILED DESCRIPTION OF THE INVENTION

The features and the advantages of the present invention will be readily understood upon a thoughtful deliberation of the following detailed description of a preferred embodiment of the present invention with reference to the accompanying drawings.

Since a multilayer structure grows easily into a diode's contact layer made of nitride semiconductor material of high conductivity (high carrier concentration), the current may not be limited to the electrode thanks to lower resistance characteristics and better current spreading. And, the contact layer made of the multilayer structure has a higher carrier concentration than the bulk layer, so the subsequent transparent electrode can easily generate Ohmic contact with it, rather than Schottky contact that leads to higher operating voltage of elements due to insufficient carrier concentration. In addition, the transparent electrode and the contact layer of multilayer structure can be made of the same conducting materials so that there is no junction between them, enabling a consistent size of the transparent electrode and the contact layer of multilayer structure.

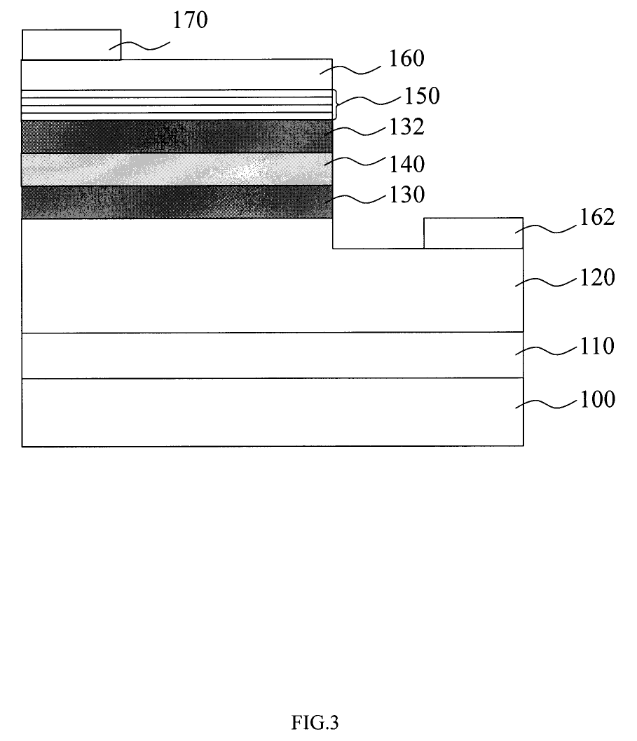

FIG. 3 depicts a cross-sectional view of a LED structure of the preferred embodiment of the present invention. Referring to FIG. 3, the structure of the present invention includes a substrate 100 made of materials such as sapphire, silicon carbide (SiC), zinc oxide (ZnO), silicon-based (Si), gallium phosphide (GaP), gallium arsenide (GaAs) and alumina (Al₂O₃). Next, a nucleation layer 110 made of AlᵤInᵥGa₁₋ᵤ₋ᵥN(u,v≧0; 0≦u+v<1) is formed on the substrate 110 with low-temperature growth method.

A first conductive buffer layer 120 can be made of Al_{c}In_{d}Ga_{1-c-d}N(c,d≧0; 0≦c+d<1). In general, it is quite difficult to form a high-quality epitaxial layer of P-type or N-type gallium nitride series compound on the substrate, owing to extremely poor matching of P-type or N-type gallium nitride series compound semiconductor and the aforementioned substrate. Thus, the nucleation layer 110 and the buffer layer 120 with gallium nitride series compound semiconductor will be firstly formed. In the embodiment, the buffer layer, made of N-type Al_{c}In_{d}Ga_{1-c-d}N, could improve both the crystallization quality of gallium nitride series compound and the yield rate of products.

An electrode 162 acting as cathode of a LED is formed on the buffer layer 120 and isolated from a lower confinement layer 130, an upper confinement layer 132 and an active layer 140. The electrode 162 can be made of Ti/Al, Ti/Al/Ti/Au, Ti/Al/Pt/Au, Ti/Al/Ni/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au, Cr/Al/Ni/Au, all of which have a good Ohmic contact with the conductive buffer layer, and a lower contact resistance.

The lower confinement layer 130 is formed on the above-specified buffer layer 120, and made of III-V group nitride compound with gallium nitride such as N-type AlₓIn_{y}Ga_{1-x-y}N(x,y≧0;0≦x+y<1;x>c) doped with N-type dopant. It should be noted that the selection of N-type dopant is familiar with those ordinary skilled in art and will not be described in detail here. Next, an active layer 140 or a light emitting layer 140, which can be made of III-V group nitride compound with gallium nitride, is disposed on the lower confinement layer 130. In the preferred embodiment, the active layer 140 can be made of AlₐIn_{b}Ga_{1-a-b}N/AlₓIn_{y}Ga_{1-x-y}N(a,b≧0;0≦a+b<1;x,y≧0;0≦x+y<1;x>c>a) quantum-well structure not doped or doped with commonly used P-type or N-type dopant. It should be noted that the selection of P-type dopant is familiar with those ordinary skilled in art and will not be described in detail here.

An upper confinement layer 132 is formed on the active layer 140, and made of III-V group nitride compound with gallium nitride, such as P-type AlₓIn_{y}Ga_{1-x-y}N(x,y≧0;0≦x+y<1;x>c) doped with commonly used P-type dopant. It should be noted that the selection of P-type dopant is familiar with those ordinary skilled in art and will not be described in detail here. The P-type or N-type active layer is covered by the lower confinement layer 130 and the upper confinement layer 132. The selection and the compound proportion of the aforementioned III-V group nitride compound with gallium nitride can be designed and utilized according to real conditions.

A contact layer 150 is formed on the upper confinement layer 132, and made of a multilayer structure formed by III-V group of high carrier concentration such as AlGaN (aluminum gallium nitride)/gallium nitride/ThinGaN (indium gallium nitride)/gallium nitride, AlGaN/gallium nitride/gallium nitride, AlGaN/ThinGaN/gallium nitride or ThinGaN/gallium nitride, with a thickness of 10˜20 angstrom/10˜20 angstrom/5˜50 angstrom/5˜50 angstrom (e.g.: AlGaN/gallium nitride/ThinGaN/gallium nitride). The P-type conducting material of the contact layer is a preferred option among P-type or N-type conducting materials, and the contact layer 150 could reduce surface impedance.

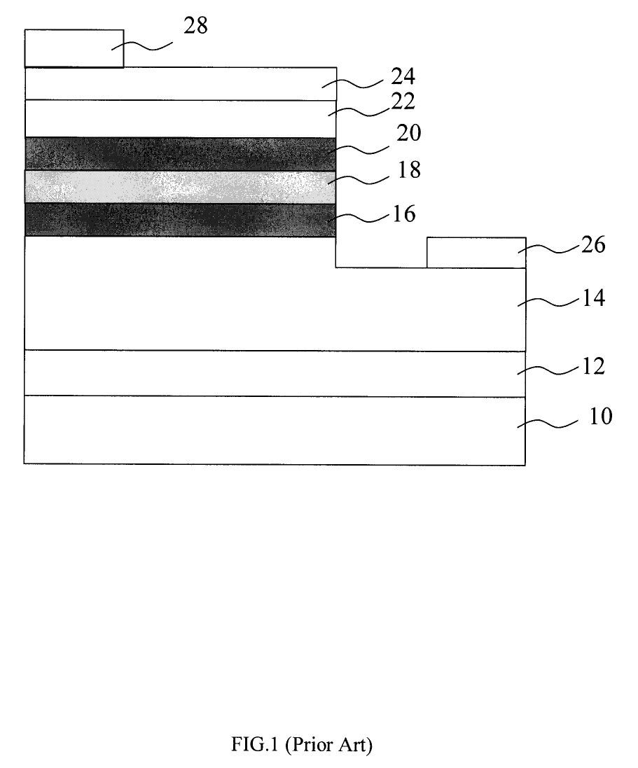

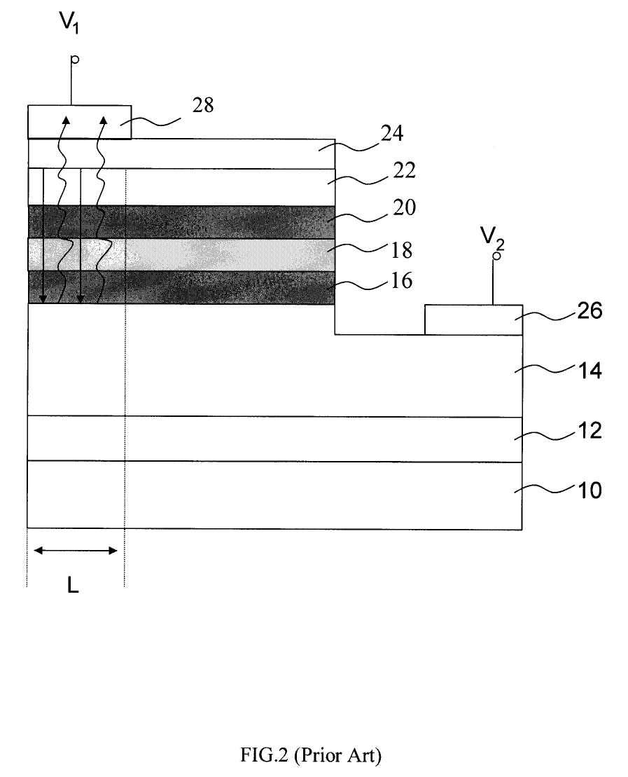

Next, a transparent electrode 160 is formed on the contact layer 150, and made of thin metal, such as: Ni/Au,Ni/Pt,Ni/Pd,Ni/Co,Pd/Au,Pt/Au,Ti/Au,Cr/Au,Sn/Au,Ta/Au,Ti N,TiWNx,Wsix, or N-type TCO(transparent conductive oxide), such as N-type conductive Indium tin oxide(ITO), Cadmium tin oxide(CTO), ZnO:Al, ZnGa₂O₄, SnO₂:Sb, Ga₂O₃:Sn, AgInO₂:Sn and In:O3:Zn, or P-type conductive TCO, e.g., CuAlO₂, LaCuOS, NiO, CuGaO₂ and SrCu₂O₂, etc. Moreover, a metal pad 170 is disposed on the transparent electrode 160 as the same as FIGS. 1 and 2. The conventional contact layer and upper confinement layer include the same semiconductor material doped with III-V group compound containing gallium nitride. In general, the contact layer contacts with the transparent electrode, so extremely high carrier concentration shall achieve quiet level, e.g. over 1×10¹⁸/cm³. As for the contact layer with P-type doping, it is very difficult to grow P-type bulk semiconductor p-Al_{c}In_{d}Ga_{1-c-d}N doped with III-V group compound containing gallium nitride, with carrier concentration over 1×10¹⁸/cm³. In the case of extremely low carrier concentration, the semiconductor will form an extremely contact resistance with the metal electrode, and more particularly to the P-type semiconductor material. Thus, the present invention provides an LED structure made of a contact layer of multilayer structure. Therefore, the P-type gallium nitride series semiconductor material of high hole concentration can be easily formed, making it a good option for the contact layer.

Since the contact layer 150 of the present invention is made of a multiple structure, e.g. AlGaN/gallium nitride/ThinGaN/gallium nitride, AlGaN/gallium nitride/gallium nitride, AlGaN/ThinGaN/gallium nitride or ThinGaN/gallium nitride, it has an excellent Ohmic contact with the transparent electrode 160, and the transparent electrode is sized to easily match the contact layer such that the structure of the present invention could increase the area in which current flows through the active layer 140 and the transparent electrode 160.

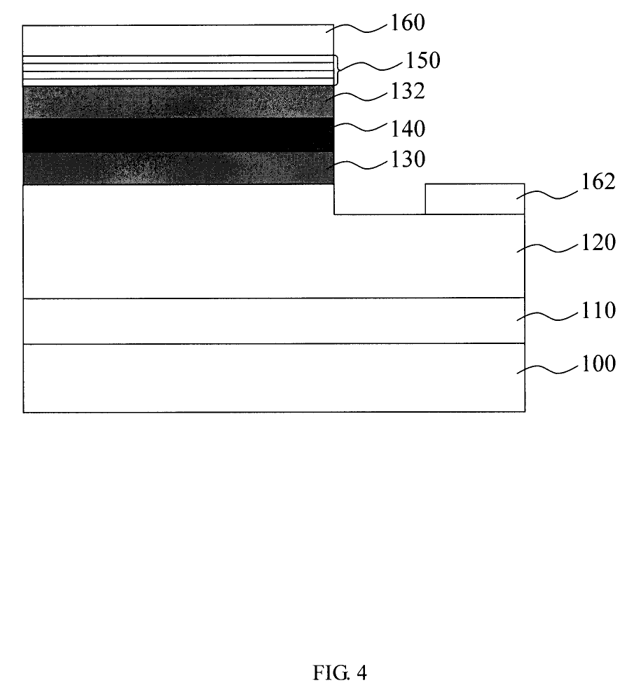

FIG. 4 depicts a schematic view of a light emitting range of a LED shown in FIG. 3. As shown in FIG. 4, when a forward bias is applied between an anode 160 (the transparent electrode) and a cathode 162, the light generated by the active layer 140 can emit through the transparent electrode, which means the light emitting area of the structure increases more than a conventional structure. So, the luminous efficiency of the LED is improved remarkably by combining the contact layer and the transparent electrode.

In addition, the contact layer of multilayer structure and the transparent electrode could employ the same conducting materials. In such case, there is no junction between the transparent electrode 160 and the contact layer 150, ensuring a smooth operation of elements, especially in the event of insufficient carrier concentration of the contact layer.

As compared with the prior art, the LED structure of the present invention has the following advantages:

The LED structure of the present invention has a contact layer made of a multilayer structure. The contact layer of high carrier concentration is easily formed.

The LED of the present invention has a contact layer made of a multilayer structure, which has a good Ohmic contact with the transparent electrode. The transparent electrode is sized to easily match the contact layer such that the current area flowing through the active layer could be increased, thereby improving the luminous efficiency and reducing the operating voltage.

The LED of the present invention has a contact layer made of a multilayer structure, which is not limited to the type of dopants. In another word, the transparent electrode and the contact layer include the same or different dopants. When the transparent electrode and the contact layer are the same conducting material, the influence against the elements caused by junction could be eliminated.

Although the invention has been explained in relation to its preferred embodiment, it is to be understood that many other possible modifications and variations can be made without departing from the spirit and scope of the invention as hereinafter claimed.

What is claimed is:

1. A LED structure, comprising:
a substrate;
a nucleation layer disposed on the substrate;
a conductive buffer layer disposed on the nucleation layer;
a first confinement layer disposed on the conductive buffer layer, wherein the first confinement layer includes the same dopant (conducting material) with the conductive buffer layer;
an active layer disposed on the first confinement layer, wherein the active layer is composed of semiconductor material mainly doped with III-V group;
a second confinement layer disposed on the active layer, wherein the second confinement layer includes a different dopant (conducting material) with the first confinement layer;
a contact layer disposed on the second confinement layer, wherein the contact layer is a multilayer structure;
an anode disposed on the contact layer; and
a cathode contacted with the conductive buffer layer, and isolated from the first and second confinement layer, the active layer, the contact layer and the anode.

2. The LED structure defined in claim 1, wherein the multilayer structure contains AlGaN/gallium nitride/ThinGaN/gallium nitride, AlGaN/gallium nitride/gallium nitride, AlGaN/ThinGaN/gallium nitride or ThinGaN/gallium nitride.

3. The LED structure defined in claim 1, wherein the anode includes metal.

4. The LED structure defined in claim 2, wherein the contact layer is made of a P-type conducting material.

5. The LED structure defined in claim 1, wherein the substrate includes as least Al2O3 (sapphire), SiC, ZnO, Si-based, GaP and GaAs.

6. The LED structure defined in claim 1, wherein the active layer is made of a semiconductor quantum-well structure mainly doped with III-V group.

7. The LED structure defined in claim 6, wherein the semiconductor compound of the quantum-well structure mainly doped with III-V group includes AlₐIn_{b}Ga_{1-a-b}N/AlₓIn_{y}Ga_{1-x-y}N, of which, a,b≧0;0≦a+b<1;x,y≧0;0≦x+y<1;x>c>a.

8. The LED structure defined in claim 1, wherein the cathode includes at least Ti/Al, Ti/Al/Ti/Au, Ti/Al/Pt/Au, Ti/Al/Ni/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au and Cr/Al/Ni/Au.

9. A LED structure, comprising:
a substrate;
a nucleation layer disposed on the substrate;
a conductive buffer layer disposed on the nucleation layer;
a first confinement layer disposed on the conductive buffer layer, wherein the first confinement layer includes the same dopant (conducting material) with the conductive buffer layer;
an active layer disposed on the first confinement layer, wherein the active layer is made of a semiconductor material mainly doped with III-V group;
a second confinement layer disposed on the active layer, wherein the second confinement layer includes a different dopant (conducting material) with the first confinement layer;
a contact layer disposed on the second confinement layer, wherein the contact layer is a multilayer structure;
a transparent electrode disposed on the contact layer; and
a cathode contacted with the conductive buffer layer, and isolated from the first and second confinement layer, the active layer, the contact layer and the anode.

10. The LED structure defined in claim 9, wherein the multilayer structure contains AlGaN/gallium nitride/ThinGaN/gallium nitride, AlGaN/gallium nitride/gallium nitride, AlGaN/ThinGaN/gallium nitride or ThinGaN/gallium nitride.

11. The LED structure defined in claim 9, wherein the transparent electrode includes metals and multilayer combinations frequently used by semiconductor manufacturing, and the total thickness of the transparent electrode is less than 0.1 um.

12. The LED structure defined in claim 11, wherein the transparent electrode includes TCO (transparent conductive oxide), N-type Indium tin oxide (ITO), Cadmium tin oxide (CTO), ZnO:Al, ZnGa₂O₄, SnO₂:Sb, Ga₂O₃:Sn, AgInO₂:Sn and In₂O₃:Zn or P-type CuAlO₂, LaCuOS, NiO, CuGaO₂ and SrCu₂O₂.

13. The LED structure defined in claim 10, wherein the contact layer is made of a P-type conducting material.

14. The LED structure defined in claim 9, wherein the substrate includes as least Al2O3 (sapphire), SiC, ZnO, Si-based, GaP and GaAs.

15. The LED structure defined in claim 9, wherein the active layer is made of a semiconductor quantum-well structure mainly doped with III-V group.

16. The LED structure defined in claim 15, wherein the semiconductor compound of the quantum-well structure mainly doped with III-V groups includes AlₐIn_{b}Ga_{1-a-b}N/AlₓIn_{y}Ga_{1-x-y}N, wherein a,b≧0;0≦a+b<1;x,y≧0;0≦x+y<1;x>c>a.

17. The LED structure defined in claim 9, wherein the cathode includes at least Ti/Al, Ti/Al/Ti/Au, Ti/Al/Pt/Au, Ti/Al/Ni/Au, Ti/Al/Pd/Au, Ti/Al/Gr/Au, Ti/Al/Co/Au, Cr/Al/Cr/Au, Cr/Al/Pt/Au, Cr/Al/Pd/Au, Cr/Al/Ti/Au, Cr/Al/Co/Au and Cr/Al/Ni/Au.

18. A LED structure, comprising:
a substrate;
a nucleation layer disposed on the substrate;
a conductive buffer layer disposed on the nucleation layer;
a first confinement layer disposed on the conductive buffer layer, wherein the first confinement layer includes the same dopant (conducting material) with the conductive buffer layer;
an active layer disposed on the first confinement layer, wherein the active layer is composed of a semiconductor material mainly doped with III-V group;
a second confinement layer disposed on the active layer, wherein the second confinement layer includes a different dopant (conducting material) with the first confinement layer;
a contact layer disposed on the second confinement layer, wherein the contact layer is a multilayer structure;
a transparent electrode disposed on the contact layer; and
an electrode contacted with the conductive buffer layer, and isolated from the first and second confinement layer, the active layer, the contact layer and the transparent electrode.

19. The LED structure defined in claim 18, wherein the multilayer structure includes AlGaN/gallium nitride/ThinGaN/gallium nitride, AlGaN/gallium nitride/gallium nitride, AlGaN/ThinGaN/gallium nitride or ThinGaN/gallium nitride.

20. The LED structure defined in claim 18, wherein the transparent electrode includes at least Ni/Au,Ni/Pt,Ni/Pd,Ni/Co,Pd/Au,Pt/Au,Ti/Au,Cr/Au,Sn/Au,Ta/Au,Ti N,TiWNx,WSix,TCO (transparent conductive oxide), N-type Indium tin oxide (ITO), Cadmium tin oxide (CTO), ZnO:Al, ZnGa₂O₄, SnO₂:Sb, Ga₂O₃:Sn, AgInO₂:Sn and In:O₃:Zn or P-type CuAlO₂, LaCuOS, NiO, CuGaO₂ and SrCu₂O₂.

21. The LED structure defined in claim 19, wherein the contact layer is made of a P-type conducting material.

22. The LED structure defined in claim 19, wherein the transparent electrode and the contact layer include a P-type or an N-type conducting material.

23. The LED structure defined in claim 19, wherein the transparent electrode includes a different conducting material with the contact layer.

24. The LED structure defined in claim 18, wherein the substrate includes as least Al2O3 (sapphire), SiC, ZnO, Si-based, GaP and GaAs.

25. The LED structure defined in claim 18, wherein the active layer is made of semiconductor quantum-well structure mainly doped with III-V group.

26. The LED structure defined in claim 25, wherein the semiconductor compound of the quantum-well structure mainly doped with III-V group includes AlₐIn_{b}Ga_{1-a-b}N/AlₓIn_{y}Ga_{1-x-y}N, wherein a,b≧0;0≦a+b<1;x,y≧0;0≦x+y<1;x>c>a.

27. The LED structure defined in claim 18, wherein the electrode includes at least Ti/Al, Ti/Al/Ti/Au, Ti/Al/Pt/Au, Ti/Al/Ni/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au and Cr/Al/Ni/Au.

28. A LED structure, comprising:
a substrate;
a conductive buffer layer disposed on the substrate;
an active layer disposed on the conductive buffer layer, wherein the active layer is made of a semiconductor material mainly doped with III-V group;
a contact layer disposed on the active layer structure;
a transparent electrode disposed on the contact layer; and
an electrode contacted with the conductive buffer layer, and isolated from the transparent electrode.

29. The LED structure defined in claim 28, wherein the transparent electrode includes at least Ni/Au,Ni/Pt,Ni/Pd,Ni/Co,Pd/Au,Pt/Au,Ti/Au,Cr/Au,Sn/Au,Ta/Au,Ti N,TiWNx,WSix,TCO (transparent conductive oxide), N-type Indium tin oxide (ITO), Cadmium tin oxide (CTO), ZnO:Al, ZnGa₂O₄, SnO₂:Sb, Ga₂O₃:Sn, AgInO₂:Sn and In₂O₃:Zn or P-type CuAlO₂, LaCuOS, NiO, CuGaO₂ and SrCu₂O₂.

30. The LED structure defined in claim 28, wherein the transparent electrode and the contact layer include a P-type or an N-type conducting material.

31. The LED structure defined in claim 28, wherein the transparent electrode includes a different conducting material with the contact layer.

32. The LED structure defined in claim 28, wherein the active layer structure comprises:
a first confinement layer disposed on the conductive buffer layer, wherein the first confinement layer includes the same conducting material with the conductive buffer layer;
an active layer disposed on the first confinement layer, wherein the active layer is made of a semiconductor material mainly doped with III-V group; and
a second confinement layer disposed on the active layer, wherein the second confinement layer includes a different conducting material with the first confinement layer.

33. The LED structure defined in claim 32, wherein the nucleation layer is disposed between the substrate and the conductive buffer layer.

34. The LED structure defined in claim 28, wherein the substrate includes at least Al2O3 (sapphire), SiC, ZnO, Si-based, GaP and GaAs.

35. A LED structure with a contact layer of a multilayer structure, comprising:
a LED body having an active layer;
a contact layer of a multilayer structure, disposed on the LED body;
a transparent electrode disposed on the contact layer of the multilayer structure, the transparent electrode being taken as anode of the LED; and
an electrode disposed on LED, wherein the electrode is not contacted with the active layer, and the electrode is taken as a cathode of the LED.

36. The LED structure with the contact layer of the multilayer structure defined in claim 35, wherein the contact layer of the multilayer structure is made of a semiconductor material doped with III-V group containing gallium nitride.

37. The LED structure with the contact layer of the multilayer structure defined in claim 36, wherein the contact layer of the multiple structure includes AlGaN/gallium nitride/ThinGaN/gallium nitride, AlGaN/gallium nitride/gallium nitride, AlGaN/ThinGaN/gallium nitride or ThinGaN/gallium nitride.

38. The LED structure with the contact layer of the multilayer structure defined in claim 35, wherein the transparent electrode includes at least Ni/Au,Ni/Pt,Ni/Pd,Ni/Co,Pd/Au,Pt/Au,Ti/Au,Cr/Au,Sn/Au,Ta/Au,Ti N,TiWNx,Wsix,TCO (transparent Conductive oxide), N-type Indium tin oxide (ITO), Cadmium tin oxide (CTO), ZnO:Al, ZnGa₂O₄, SnO₂:Sb, Ga₂O₃:Sn, AgInO₂:Sn and In₂O₃:Zn or P-type CuAlO₂, LaCuOS, NiO, CuGaO₂ and SrCu₂O₂.

39. The LED structure with the contact layer of the multilayer structure defined in claim 35, wherein the contact layer of the multiple structure is made of a P-type conducting material.

40. The LED structure with the contact layer of the multilayer structure defined in claim 35, wherein the transparent electrode and the contact layer of the multiple structure are made of a P-type or an N-type conducting material.

41. The LED structure with the contact layer of the multilayer structure defined in claim 35, wherein the transparent electrode includes a different conducting material with the super crystal contact layer.
